(19) United States
(12) Patent Application Publication
(10) Pub. No.: US 2018/0175817 A1
(43) Pub. Date: Jun. 21, 2018

(54) METHOD TO DESIGN CERAMIC FILTERS WITH FINITE TRANSMISSION ZEROS

(71) Applicant: Futurewei Technologies, Inc., Plano, TX (US)

(72) Inventors: Huairen Yi, Somerset, NJ (US); Zhengxiang Ma, Summit, MA (US)

(21) Appl. No.: 15/408,480

(22) Filed: Jan. 18, 2017

Related U.S. Application Data
(60) Provisional application No. 62/436,197, filed on Dec. 19, 2016.

(51) Int. Cl. H03H 7/01; H03H 7/46; H04B 1/40

(52) U.S. Cl. CPC H03H 7/0123; H04W 88/08; H04B 1/40; H03H 7/46

(57) ABSTRACT

An apparatus comprises a bandpass circuit having a passband frequency range, wherein the bandpass circuit includes a first building block circuit including one ceramic resonator circuit element, wherein the building block circuit is a one pole filter circuit and a transfer function of the first building block circuit includes one finite transmission zero, and wherein a transfer function of the bandpass circuit includes the finite transmission zero at one of a frequency lower than the passband frequency range or a frequency higher than the passband frequency range.

### CLAIM OF PRIORITY

This application claims the benefit of priority under 35 U.S.C. § 119(e) to U.S. Provisional Patent Application Ser. No. 62/436,197, filed on Dec. 19, 2016, which is hereby incorporated by reference herein in its entirety.

### FIELD OF THE INVENTION

The present disclosure relates to elliptical filter circuits, and in particular to elliptical filter circuits that include ceramic filters.

### BACKGROUND

Radio access networks are used for delivering data, voice and video communications to devices such as cellular telephones, smart phones, tablet computers, etc. Ceramic filters are often used in wireless base station applications (e.g., in RF transceivers) due to their relatively low cost, small size, moderate unloaded quality factor, and reasonably power handling capabilities. Ceramic filters can include ceramic resonators. A ceramic resonator may include a coaxial resonator filled with low loss and temperature stable ceramic materials. Two types of coaxial resonators can be used: a quarter-wave short and a half-wave open. The quarter-wave short has metal film applied to one end, and the half-wave open has both ends un-metallized.

Some base station applications require the use of elliptic function filtering due to the tight rejection requirements. The transition into the high impedance mode of a ceramic resonator can have a very high quality or Q factor making them desirable for elliptical filters, but designing elliptical filters with ceramic filters can be challenging. Existing approaches can have undesirable insertion loss, large package size, and high production cost. Thus, there are general needs for devices, systems and methods that provide robust communication in radio access devices and that are also easy to implement.

### SUMMARY

Embodiments pertain to elliptical filter circuits that include ceramic filters. Ceramic filters include ceramic resonators as circuit elements. These circuits are useful for radio frequency (RF) base stations, but elliptical filter functions can be difficult to implement with ceramic filters. This is because implementing finite transmission zeros (FTZs) with ceramic filters can lead to designs that are physically large and have unacceptable insertion loss.

The present subject matter provides building block circuits to implement FTZs in filtering circuits using ceramic resonators. The building block circuits can be combined to implement any number of FTZs on the higher side or lower side of the passband of the elliptical filters.

A first apparatus example includes a bandpass circuit having a passband frequency range, wherein the bandpass circuit includes a first building block circuit including one ceramic resonator circuit element, wherein the building block circuit is a one pole filter circuit and a transfer function of the first building block circuit includes one finite transmission zero, and wherein a transfer function of the bandpass circuit includes the finite transmission zero at one of a frequency lower than the passband frequency range or a frequency higher than the passband frequency range.

A second apparatus example includes an antenna diplexer circuit including: a lower frequency channel configured to carry radio frequency (RF) signals of a first range of frequencies, wherein the lower frequency channel includes an M-pole elliptical filter circuit including M ceramic resonator circuit elements, wherein a transfer function of the lower frequency channel includes up to M finite transmission zeros, and wherein M is a positive integer greater than zero; and a higher frequency channel configured to carry radio frequency (RF) signals of a second range of frequencies higher than the first range of frequencies, wherein the higher frequency channel includes an N-pole elliptical filter circuit including N ceramic resonator circuit elements, wherein a transfer function of the lower frequency channel includes up to N finite transmission zeros, and wherein N is a positive integer greater than zero.

This section is intended to provide an overview of subject matter of the present patent application. It is not intended to provide an exclusive or exhaustive explanation of the invention. The detailed description is included to provide further information about the present patent application such as a discussion of the dependent claims and the interrelation of the dependent and independent claims in addition to the statements made in this section.

### BRIEF DESCRIPTION OF THE DRAWINGS

FIG. 1 is a circuit diagram of an example of a bandpass circuit including a one pole building block circuit.

FIG. 2 is a graph of the frequency response of the bandpass circuit of FIG. 1.

FIG. 3 is a circuit diagram of another example of a bandpass circuit including a one pole building block circuit.

FIG. 4 is a graph of the frequency response of the bandpass circuit of FIG. 3.

FIG. 5 is a circuit schematic of an example of a three pole filter circuit.

FIG. 6 is a graph of the frequency response of the three pole filter circuit of FIG. 5.

FIG. 7 is a circuit schematic of another example of a three pole filter circuit.

FIG. 8 is a graph of the frequency response of the three pole filter circuit of FIG. 7.

FIG. 9 is a circuit schematic of an example of a five pole filter circuit.

FIG. 10 is a graph of the frequency response of the five pole filter circuit of FIG. 9.

FIG. 11 is a block diagram of an example of an RF antenna diplexer.

FIG. 12 is a circuit schematic of an example of an antenna diplexer.

FIGS. 13-15 are graphs of the different aspects of the frequency response of the antenna diplexer of FIG. 12.

### DETAILED DESCRIPTION

In the following description, reference is made to the accompanying drawings that form a part hereof, and in which is shown by way of illustration specific embodiments which may be practiced. These embodiments are described in sufficient detail to enable those skilled in the art to practice the invention, and it is to be understood that other embodiments may be utilized and that structural, logical and electrical changes may be made without departing from the scope of the present invention. The following description of example embodiments is, therefore, not to be taken in a limited sense, and the scope of the present invention is defined by the appended claims.

The functions or algorithms described herein may be implemented in software in one embodiment. The software may consist of computer executable instructions stored on computer readable media or computer readable storage device such as one or more non-transitory memories or other type of hardware based storage devices, either local or networked. Further, such functions correspond to modules, which may be software, hardware, firmware or any combination thereof. Multiple functions may be performed in one or more modules as desired, and the embodiments described are merely examples. The software may be executed on a digital signal processor, ASIC, microprocessor, or other type of processor operating on a computer system, such as a personal computer, server or other computer system, turning such computer system into a specifically programmed machine.

As indicated previously herein, it can be desirable to implement elliptical filtering with ceramic filters, but the implementation can be challenging and expensive in terms of cost and size. Elliptical filter transfer functions can be realized by using circuits that add finite transmission zeros (FTZs) into the circuit transfer function, but implementing FTZs with ceramic filters can result in designs with undesirable characteristics.

One approach is to cascade a notch filter with a bandpass filter. Although it can work for some applications, in general this may not be an efficient design because the cascaded notch filter introduces additional insertion loss, larger package size, and added production cost. Another approach is to use a technique in which resonant sections of the filter circuit are cross coupled, i.e., electrical couplings are introduced between non-adjacent resonators. With appropriate coupling orientations (or signs) with respect to sequential resonator couplings, finite transmission zeros can be produced close to the passband. The maximum number of FTZs that can be realized with the cross coupling technique is equal to the number of resonators minus two (e.g. one FTZ for three resonators, two FTZs for four resonators, etc.). The cross coupling technique works well for cavity filter designs, but for ceramic filter designs it is more difficult to introduce cross coupling between the non-adjacent resonators, especially to introduce the desired cross couplings between specific resonators with the appropriate signs. Also the number of cross couplings that can be used is limited, making it difficult to realize the desired number of FTZs at the desired frequency location in the transfer function.

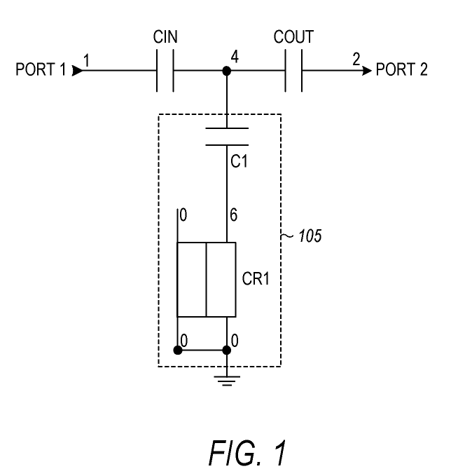

FIG. 1 is a circuit diagram of an example of a bandpass circuit including a one pole building block circuit 105. The bandpass circuit can be a one pole elliptical filter circuit. The bandpass circuit also includes input capacitor Cin and output capacitor Cout. Capacitors Cin and Cout are for impedance transformations, (e.g., to provide matching between the building block circuit and other circuits). The building block circuit 105 includes one ceramic resonator circuit element CR1 connected in series to capacitor C1. The building block circuit 105 is operatively coupled to capacitors Cin and Cout. Capacitor C1 is connected to capacitors Cin and Cout, and the ceramic resonator CR1 is connected to circuit ground.

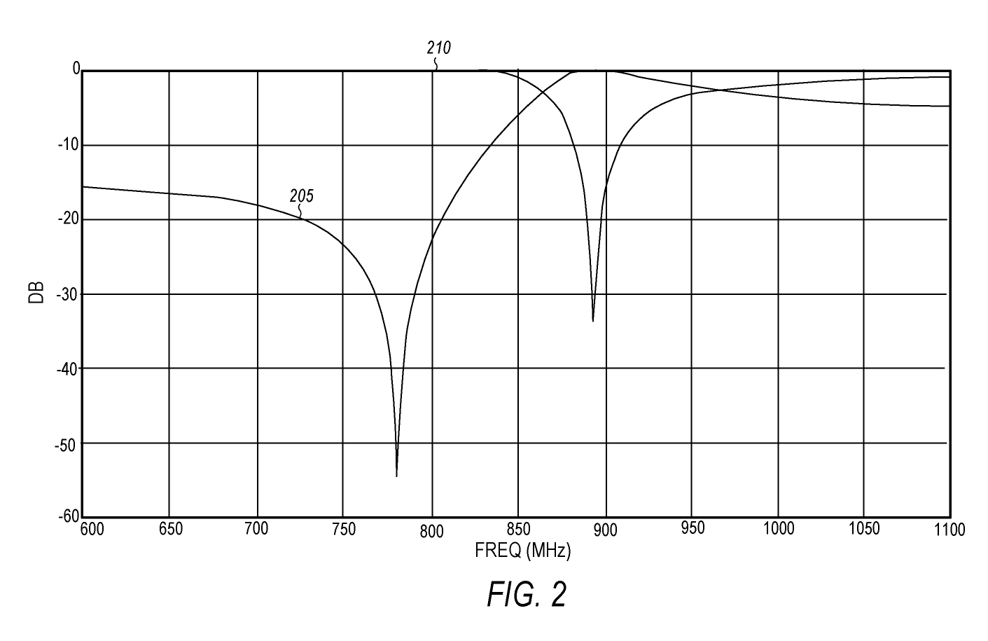

FIG. 2 is a graph of the frequency response of the bandpass circuit of FIG. 1. The frequency response of the reflected signal is shown as waveform 210, and the frequency response of the transmitted signal is shown as waveform 205. Waveforms 210 and 205 show that the bandpass circuit has a passband center frequency at about 890 megahertz (890 MHz). It is desired to attenuate signals at the lower side of the passband. Waveform 205 shows that the building block circuit 105 adds one FTZ to the transfer function at a frequency lower than the passband frequency range. In FIG. 2, the FTZ is produced at about 780 MHz. The internal circuit impedance is determined by the passband bandwidth, passband center frequency, and the characteristic impedance of the ceramic resonator CR1. C1 and CR1 form a complex resonator with a transmission maximum (passband) and a finite transmission zero (FTZ) below the passband. When C1 is infinity, the FTZ moves to DC (i.e. toward 0 Hz). When C1 becomes smaller and smaller, the FTZ moves closer and closer to the passband, while the passband also moves higher and higher in frequency. Thus, the value of the FTZ introduced by the building block circuit 105 can be tuned close to the passband or away from the passband by adjusting the value of capacitor C1 and the resonant frequency of the ceramic resonator CR1.

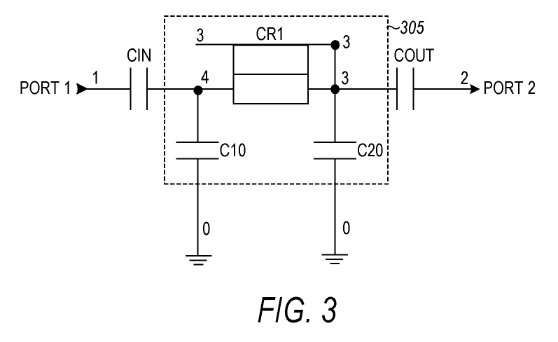

FIG. 3 is a circuit diagram of another example of a bandpass circuit including a one pole building block circuit 305. As in FIG. 1, capacitors Cin and Cout are the input and output capacitors to the bandpass filter circuit, respectively. The building block circuit 305 includes one ceramic resonator CR1 and two capacitors C10 and C20. The building block circuit 305 is operatively coupled between the Cin and Cout capacitors. Capacitor C10 is connected to capacitor Cin and circuit ground, and capacitor C20 is connected to capacitor Cout and circuit ground.

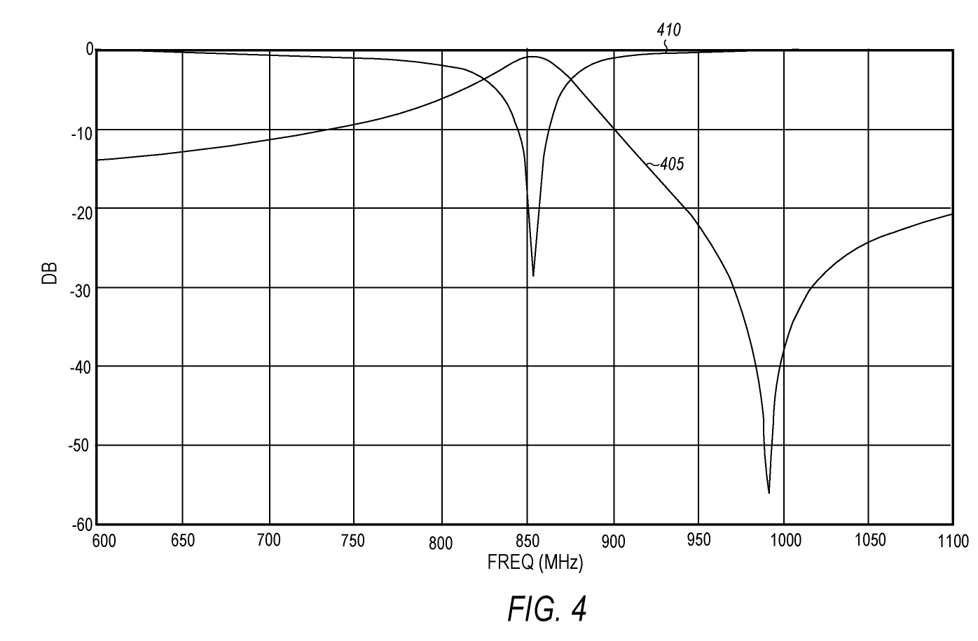

FIG. 4 is a graph of the frequency response of the bandpass circuit of FIG. 3. The frequency response of the reflected signal is shown as waveform 410 and the transmitted signal is shown as waveform 405. Waveforms 410 and 405 show that the bandpass circuit has a passband center frequency at about 855 megahertz (855 MHz). It is desired to attenuate signals at the higher side of the passband. Waveform 405 shows that the building block circuit 305 adds one FTZ to the transfer function at a frequency higher than the passband frequency range. In FIG. 4, the FTZ is produced at about 990 MHz. For the high side building block circuit, capacitors Cin and Cout not only provide impedance transformation between the internal impedance and outside impedance similar to the low side building block circuit, but also contribute in determining the passband bandwidth and passband center frequency. The high side FTZ is determined by the ceramic resonator CR1. Capacitors C10 and C20 mainly determine the distance between the passband frequency and the transmission zero frequency. Higher value of C10 and C20 moves the passband lower (away from the FTZ) and lower value of C10 and C20 move the passband closer to the FTZ. The value of the FTZ introduced by the building block circuit 305 can be tuned close to the passband or away from the passband by adjusting the value of capacitors C10 and C20 and the resonant frequency of the ceramic resonator CR1.

The building block circuits 105 and 305 of FIG. 1 and FIG. 3 can be used as basic building block circuits to implement many different types of elliptical filters simply by cascading them as needed. For instance, higher order filters with sharp edge rejection on the lower side of the passband can be implemented by cascading two or more of the building block circuits of FIG. 1.

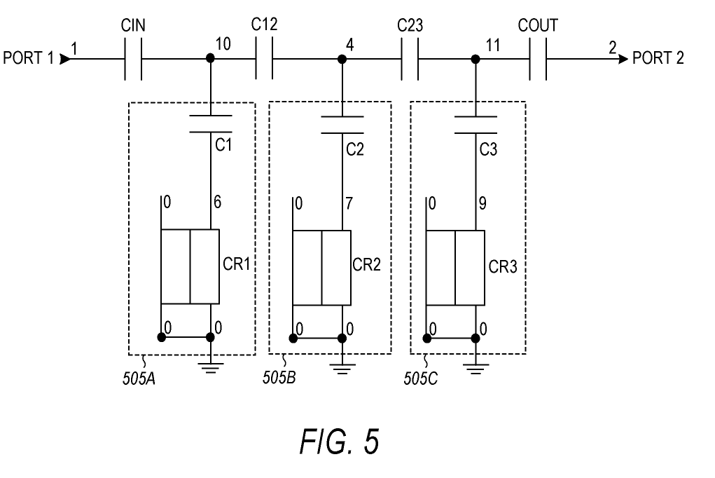

FIG. 5 is a schematic of an example of a three pole filter circuit implemented by cascading three of the basic building block circuits of FIG. 1. A three pole filter circuit provides sharper rejection than a one pole filter circuit. The bandpass filter circuit includes coupling capacitors Cin, C12, C23, Cout, and three basic building block circuits 505A-505C connected as shown.

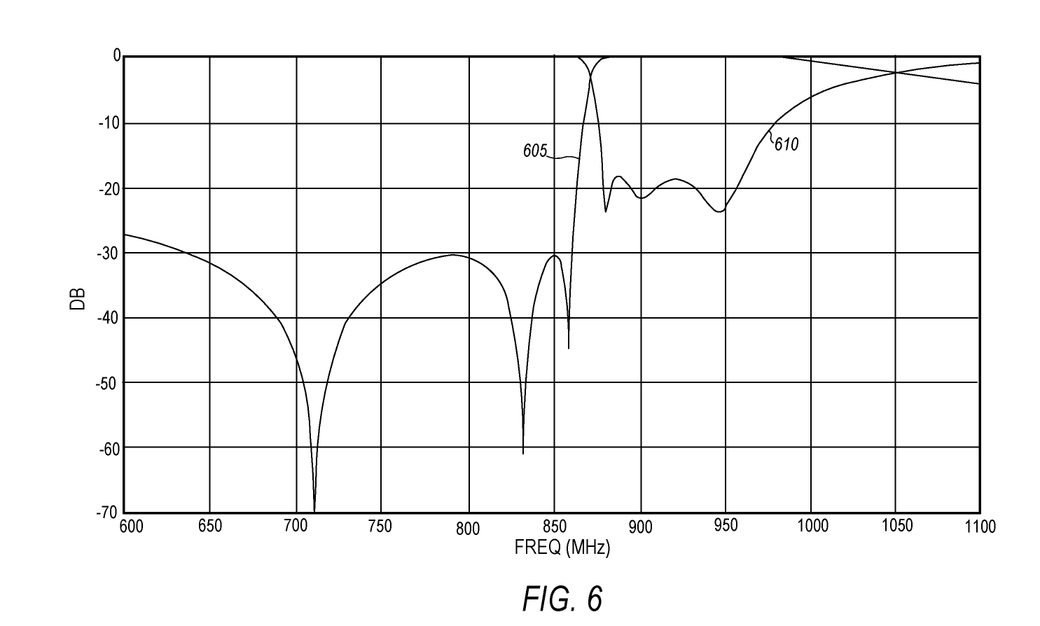

FIG. 6 is a graph of the frequency response of the bandpass circuit of FIG. 5. Waveform 610 is the frequency response of the reflected signal, and waveform 605 is the frequency response of the transmitted signal. Waveform 605 shows the three FTZs produced by the three building block circuits 505A-505C on the lower side of the passband at about 710 MHz, 830 MHz, and 860 MHz. Cascading three of the higher-side zero basic building block circuits of FIG. 3 would produce three FTZs on the higher side of the pass band.

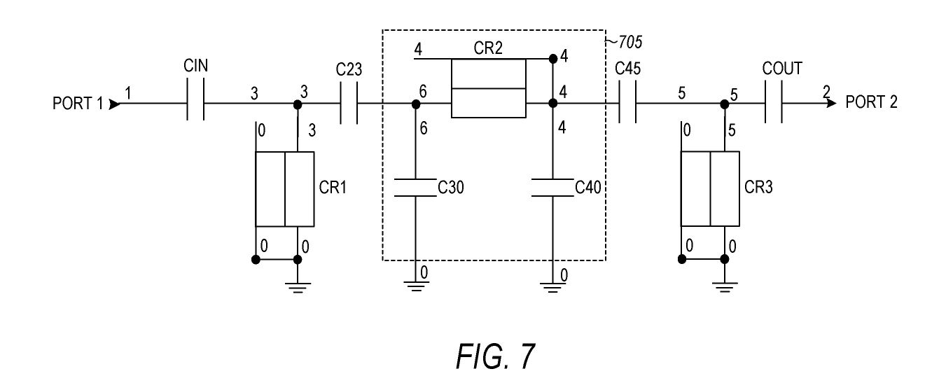

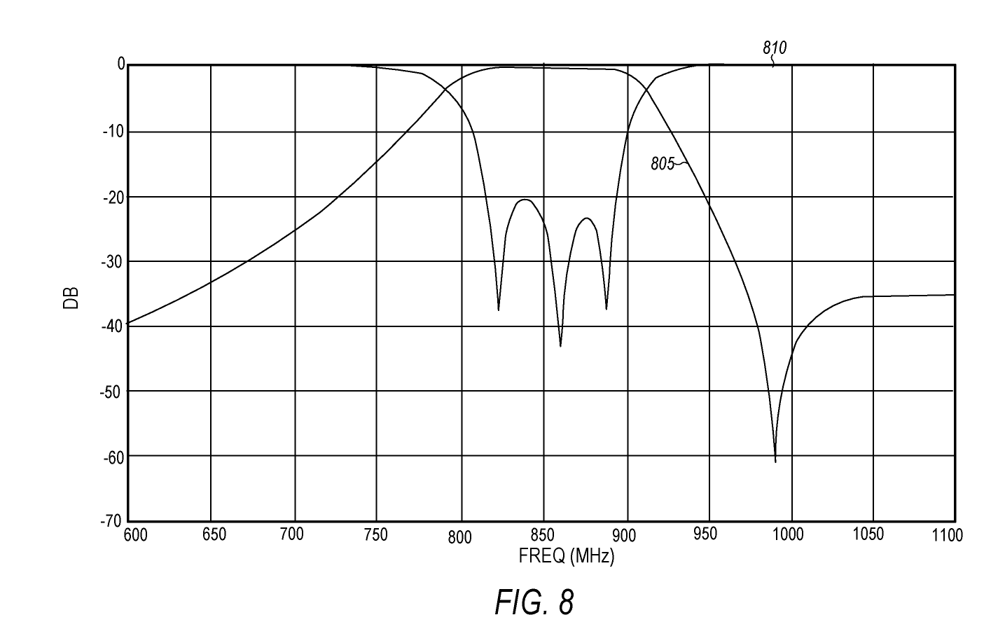

The basic building block circuits can also be combined with normal ceramic resonator circuit elements to produce filter transfer functions. FIG. 7 shows a three pole filter design that includes coupling capacitors Cin, C23, C45, and Cout, a higher-side zero basic building block circuit 705 (shown as 305 in FIG. 3), and two normal ceramic resonator circuit elements CR1 and CR3. FIG. 8 is a graph of the frequency response of the bandpass circuit of FIG. 7. Waveform 810 is the frequency response of the reflected signal, and waveform 805 is the frequency response of the transmitted signal. In this filter design, only one FTZ is produced on the higher side of passband as shown by waveform 805.

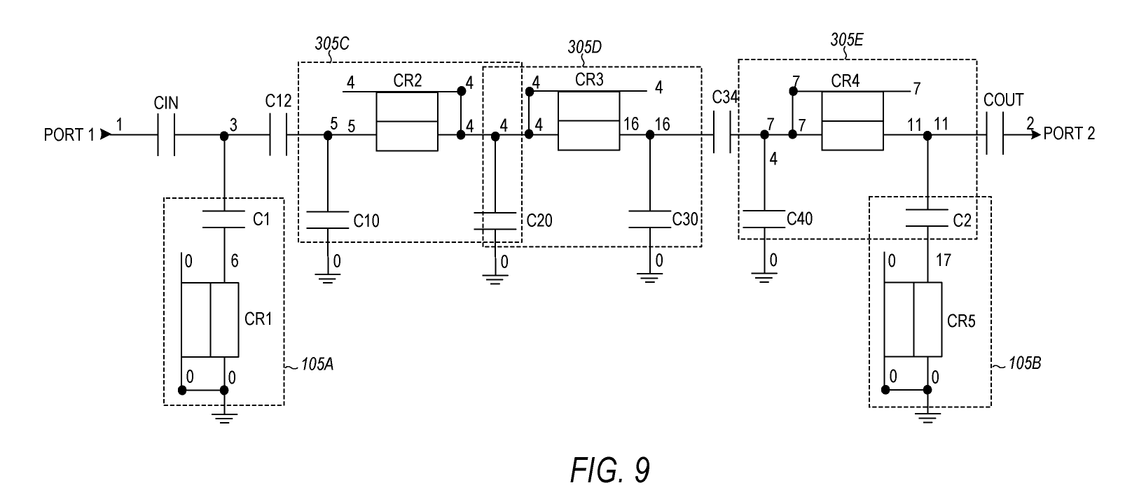

In another example, cascading one or more of the lower side FTZ building block circuits 105 of FIG. 1 with one or more of the higher side building block circuits 305 of FIG. 3 will produce FTZs on both the lower and higher sides of the passband. FIG. 9 is a schematic of an example of a five pole filter circuit implemented by cascading two lower side building block circuits 105A and 105B with three higher side building block circuits 305C, 305D, and 305E. The bandpass circuit also includes capacitors Cin, C12, C34, and Cout. The circuit schematic is shown after circuit transformation and simplifications are implemented. For instance, capacitor C20 is a combined capacitance shared between building block circuits 305C and 305D, and another grounding capacitor of circuit 305E is combined with capacitor C2 and the intrinsic capacitance of ceramic resonator circuit element CR5.

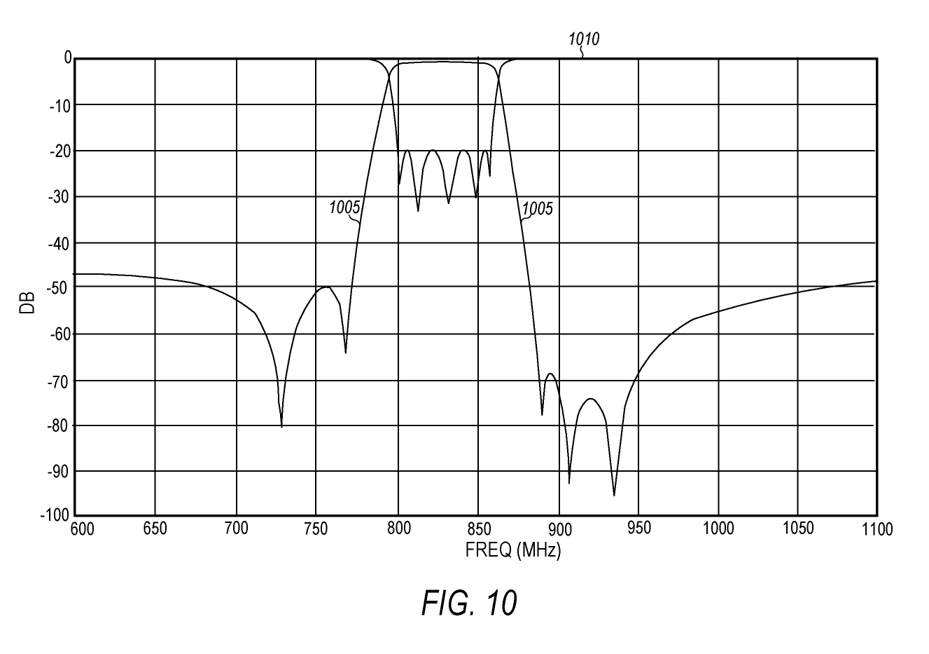

FIG. 10 is a graph of the frequency response of the five pole filter circuit of FIG. 9. Waveform 1010 is the frequency response of the reflected signal, and waveform 1005 the frequency response of the transmitted signal. Waveform 1005 shows five FTZs in total, two on the lower side of the passband and three on the higher side of the passband.

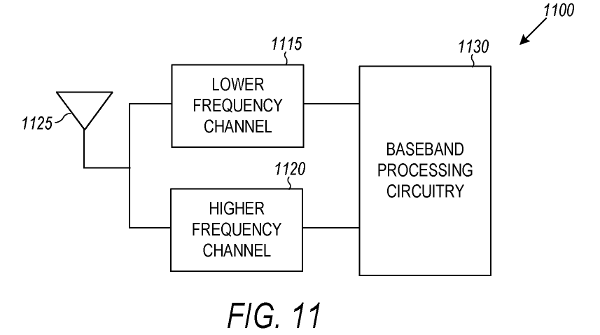

Elliptical filters can be useful in antenna diplexer circuits. An antenna diplexer circuit multiplexes signals of different frequency domains or ranges to the same antenna or antennas. FIG. 11 is a block diagram of an example of an RF antenna diplexer. The RF antenna diplexer may be included in a wireless base station. The antenna diplexer 1100 includes a lower frequency channel 1115 and a higher frequency channel 1120. The lower frequency channel 1115 and the higher frequency channel 1120 share a common port operatively coupled to an RF antenna 1125. The antenna 1125 can include one or more directional or omnidirectional antennas. The other ends of the frequency channels can be operatively coupled to baseband processing circuitry 1130.

To maximize the isolation between the two channels of a diplexer, it is beneficial to place all the FTZs on the higher side of the passband for the low band channel, and all FTZs on the lower side of the passband for the high band channel. The basic building block circuits are advantageous for this kind of design requirement.

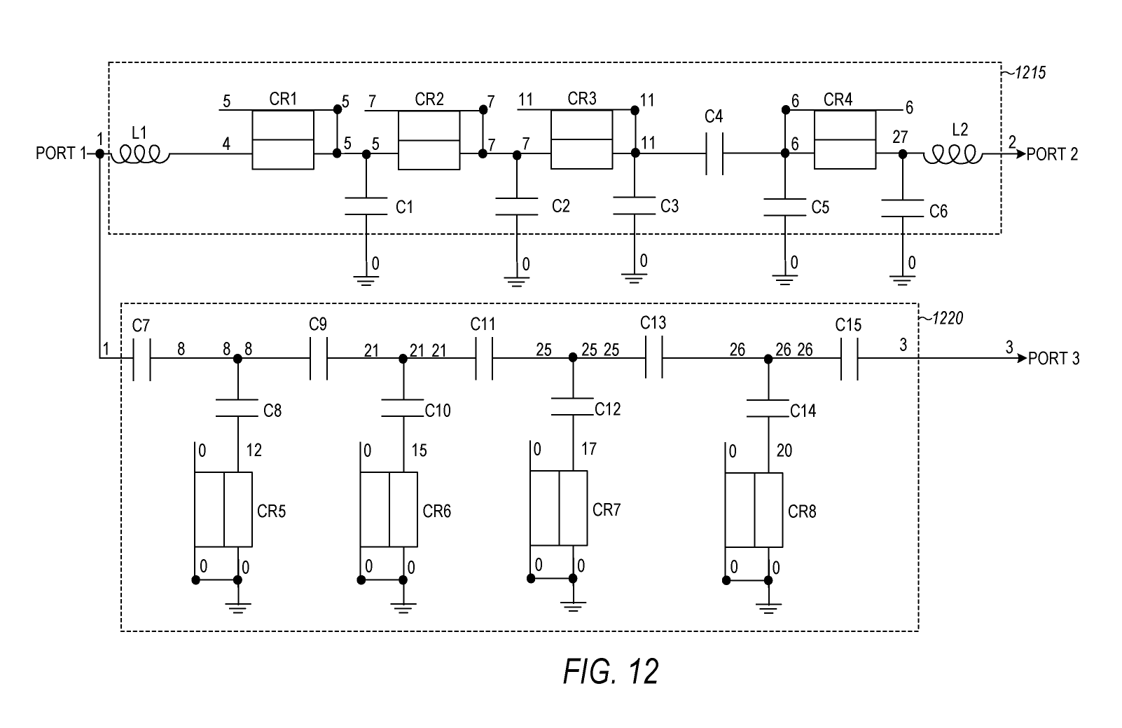

FIG. 12 is a circuit diagram of an example of an antenna diplexer circuit including a lower frequency channel 1215 and a higher frequency channel 1220. The lower frequency channel and the higher frequency channel share a common port (Port 1) operatively coupled to an RF antenna. The higher frequency channel carries RF signals for a range of frequencies higher than the lower range of frequencies carried by the lower frequency channel.

For the lower frequency channel 1215, all the FTZs are placed on the higher side of the passband. The lower frequency channel 1215 includes four of the higher side building block circuits of FIG. 3, each including one ceramic resonator circuit element. For the higher frequency channel 1220, all the FTZs are placed on the lower side of the passband. The higher frequency channel 1220 includes four of the lower side building block FTZ circuits of FIG. 1, each including one ceramic resonator circuit element.

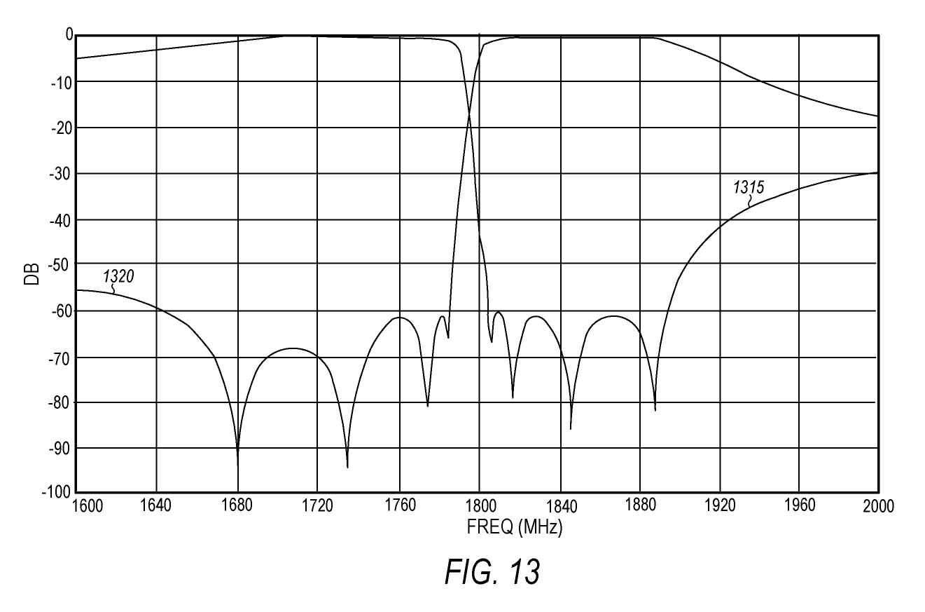

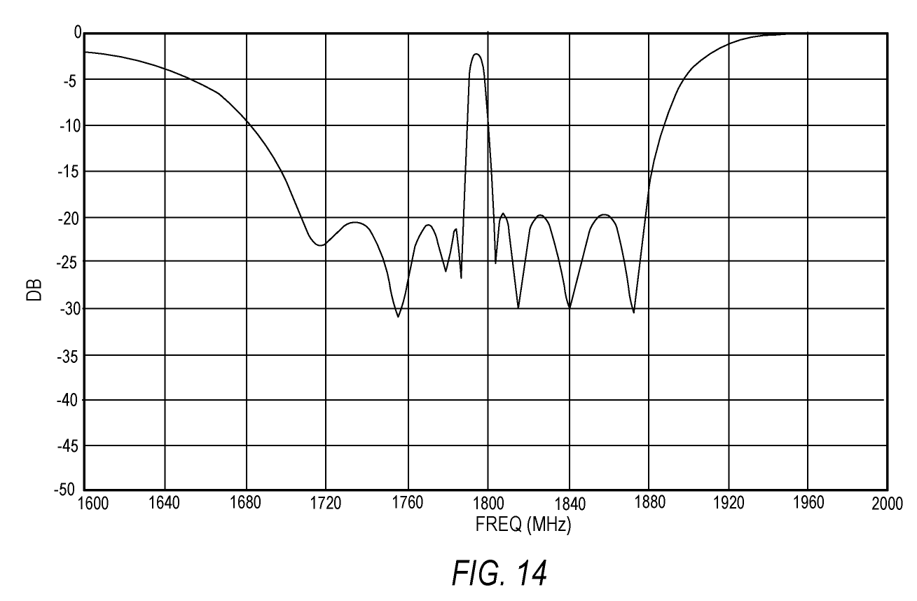

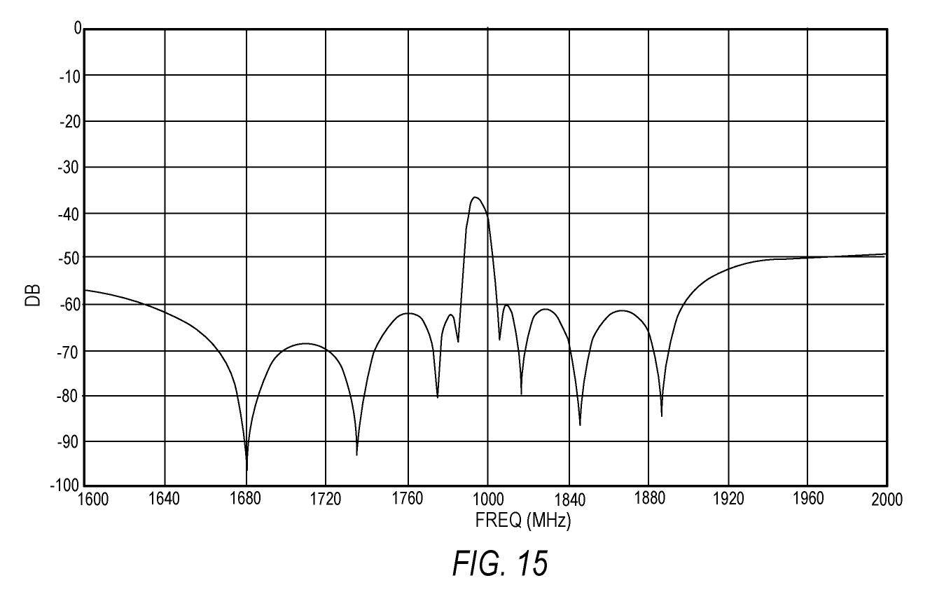

FIG. 13 is a graph of the frequency response of the lower frequency channel and the higher frequency channel of the diplexer circuit. Waveform 1320 corresponds to the higher frequency channel and includes four FTZs. Waveform 1315 corresponds to the lower frequency channel and also includes four FTZs. FIG. 14 is a graph of a waveform of the reflected signals at the common port, and FIG. 15 is a graph of a waveform of the isolation between the two channels. The waveforms show that the FTZs produced using the building block circuits provide a very sharp rejection between the two channels. The example antenna diplexer of FIG. 12 uses a four pole filter for the lower frequency channel and the higher frequency channel, respectively. Other configurations can be implemented using building block circuits. In the general case, the lower frequency channel can include an M-pole elliptical filter circuit using M higher side building block circuits of FIG. 3, and the higher frequency channel can include an N-pole elliptical filter using N lower side building block circuits of FIG. 1, where M and N are positive integers.

The several examples described herein have distinctive advantages over previous approaches to produce elliptical function ceramic filters. The transfer functions are easily implemented using the basic building block circuits. No additional ceramic resonators are required as in the cascaded notch filter approach. No cross couplings of resonant sections are required as in the cross coupled approach. All that is required is to add one or more additional capacitors in the circuit. Additionally, for a given number of ceramic resonators, it can produce more FTZs than any other methods, and therefore is the most efficient way to generate FTZs. For example, for an N pole filter consisting of N resonators, this method can produce N FTZs while the cross coupled method can only produce a maximum of N−2 FTZs. Further, implementing the elliptical filters with the basic building block circuits is a very flexible method to place the FTZs at the desired frequency locations to meet the rejection or isolation requirements.

### Additional Description and Examples

Example 1 can include subject matter (such as an apparatus) comprising: a bandpass circuit having a passband frequency range, wherein the bandpass circuit includes a building block circuit that includes one ceramic resonator circuit element, wherein the building block circuit is a one pole filter circuit and adds one finite transmission zero to a transfer function of the bandpass circuit at one of a frequency lower than the passband frequency range or a frequency higher than the passband frequency range.

In Example 2, the subject matter of Example 1 optionally includes a second building block circuit that is a one pole filter circuit, wherein the second building block circuit includes only a second ceramic resonator circuit element, wherein the first building block circuit adds one finite transmission zero at the frequency lower than the passband frequency range and the second building block circuit adds one finite transmission zero at the frequency higher than the passband frequency range.

In Example 3, the subject matter of Example 2 optionally includes a first building block circuit includes a first capacitor coupled in series to the first ceramic resonator circuit, and the first ceramic resonator circuit element is coupled to the first capacitor and circuit ground, and a second building block circuit that includes a second capacitor and a third capacitor each coupled to the second ceramic resonator circuit element and to circuit ground.

In Example 4, the subject matter of one or any combination of Examples 1-3 optionally includes at least one second building block circuit that is a one pole elliptical filter circuit and includes one ceramic resonator circuit element, and a first building block circuit that adds one finite transmission zero at the frequency lower than the passband frequency range and the at least one second building block circuit adds a second finite transmission zero at the same or a different frequency lower than the passband frequency range.

In Example 5, the subject matter of Example 4 optionally includes a first building block circuit includes a first capacitor coupled in series to the first ceramic resonator circuit element, wherein the first ceramic resonator circuit element is coupled to the first capacitor and circuit ground, and at least one second building block circuit that includes a second capacitor coupled in series to the one ceramic resonator circuit element of the second building block circuit, and the one ceramic resonator circuit element of the second building block circuit is coupled to the second capacitor and circuit ground.

In Example 6, the subject matter of one or any combination of Examples 1-5 optionally includes at least one second building block circuit that is a one pole elliptical filter circuit and includes one ceramic resonator circuit element, and a first building block circuit that adds one finite transmission zero at the frequency higher than the passband frequency range and the at least one second building block circuit adds a second finite transmission zero at the same or different frequency higher than the passband frequency range.

In Example 7, the subject matter of Example 6 optionally includes first building block circuit includes the first ceramic resonator circuit element coupled between a first capacitor and a second capacitor, and the first capacitor and the second capacitor are coupled to the first ceramic resonator circuit element and circuit ground, and at least one second building block circuit that includes a third capacitor coupled in series to the one ceramic circuit element of the second building block circuit, and the one ceramic circuit element is coupled to circuit ground.

In Example 8, the subject matter of one or any combination of Examples 1-7 optionally includes the first building block circuit being included in N building block circuits, wherein each of the N building block circuits includes only one ceramic resonator circuit element and adds one finite transmission zero to a transfer function of the combined bandpass circuit and N building block circuits, wherein M of the N building block circuits add finite transmission zeros at frequencies lower than the passband frequency range and N−M of the building block circuits add finite transmission zeros at frequencies higher than the passband frequency range, wherein N and M are positive integers and N>M.

In Example 9, the subject matter of one or any combination of Examples 1-8 optionally includes the bandpass circuit being operatively coupled to bandpass processing circuitry.

Example 10 can include subject matter (such as an apparatus), or can optionally be combined with one or any combination of Examples 1-9 to include such subject matter, comprising: an antenna diplexer circuit including: a lower frequency channel configured to carry radio frequency (RF) signals of a first range of frequencies, wherein the lower frequency channel includes an M-pole elliptical filter circuit including M ceramic resonator circuit elements, wherein a transfer function of the lower frequency channel includes up to M finite transmission zeros, and wherein M is a positive integer greater than zero; and a higher frequency channel configured to carry radio frequency (RF) signals of a second range of frequencies higher than the first range of frequencies, wherein the higher frequency channel includes an N-pole elliptical filter circuit including N ceramic resonator circuit elements, wherein a transfer function of the lower frequency channel includes up to N finite transmission zeros, and wherein N is a positive integer greater than zero.

In Example 11, the subject matter of Example 10 optionally includes the higher frequency channel including N circuit blocks and a bandpass circuit, wherein a circuit block of the N circuit blocks includes a capacitor and one ceramic resonator circuit element of the N ceramic circuit elements, wherein the capacitor is coupled in series to the one ceramic resonator circuit element, and the one ceramic resonator circuit element is coupled to the capacitor and circuit ground.

In Example 12, the subject matter of one or both of Examples 10 and 11 optionally includes the lower frequency channel including M circuit blocks and a bandpass circuit, wherein a circuit block of the M circuit blocks includes a capacitor and one ceramic resonator circuit element of the M ceramic circuit elements, wherein the capacitor is coupled to the one ceramic resonator circuit element and circuit ground.

In Example 13, the subject matter of one or any combination of Examples 10-12 optionally includes an antenna operatively coupled to a port common to the lower frequency channel and the higher frequency channel.

In Example 14, the subject matter of one or any combination of Examples 10-13 optionally includes the antenna diplexer circuit being operatively coupled to baseband processing circuitry.

Example 15 can include subject matter (such as a wireless base station), or can optionally be combined with one or any combination of Examples 1-14 to include such subject matter comprising: a radio frequency (RF) antenna; and a bandpass circuit having a passband frequency range, wherein the bandpass circuit includes a building block circuit including only a first ceramic resonator circuit element, wherein the building block circuit is a one pole filter circuit and adds one finite transmission zero to a transfer function of the bandpass circuit at one of a frequency lower than the passband frequency range or a frequency higher than the passband frequency range.

In Example 16, the subject matter of Example 15 can optionally include a second building block circuit that is a one pole filter circuit, wherein the second building block circuit includes only a second ceramic resonator circuit element, wherein the first building block circuit adds one finite transmission zero at the frequency lower than the passband frequency range and the second building block circuit adds one finite transmission zero at the frequency higher than the passband frequency range.

In Example 17, the subject matter of one or both of Examples 15 and 16 optionally includes at least one second building block circuit that is a one pole filter circuit and includes one ceramic resonator circuit element, wherein the first building block circuit adds one finite transmission zero at the frequency lower than the passband frequency range and the at least one second building block circuit adds a second finite transmission zero at the same or a different frequency lower than the passband frequency range.

In Example 18, the subject matter of one or any combination of Examples 15-17 optionally includes at least one second building block circuit that is a one pole filter circuit and includes one ceramic resonator circuit element, wherein the first building block circuit adds one finite transmission zero at the frequency higher than the passband frequency range and the at least one second building block circuit adds a second finite transmission zero at the same or different frequency higher than the passband frequency range.

In Example 19, the subject matter of one or any combination of Examples 15-18 optionally includes the first building block circuit being included in an N-pole filter circuit that includes N ceramic resonator circuit elements, wherein a transfer function of the filter circuit includes N finite transmission zeros.

In Example 20, the subject matter of one or any combination of Examples 15-19 optionally includes baseband processing circuitry operatively coupled to the bandpass circuit.

These non-limiting examples can be combined in any permutation or combination.

Although a few embodiments have been described in detail above, other modifications are possible. For example, the logic flows depicted in the figures do not require the particular order shown, or sequential order, to achieve desirable results. Other steps may be provided, or steps may be eliminated, from the described flows, and other components may be added to, or removed from, the described systems. Other embodiments may be within the scope of the following claims.

1. An apparatus comprising:
a bandpass circuit having a passband frequency range, wherein the bandpass circuit includes a first building block circuit including a first circuit path from an input to an output of the first building block circuit, one ceramic resonator circuit element arranged in the first circuit path, a first capacitor arranged from an input side of the ceramic resonator to circuit ground, and a second capacitor arranged from an output side of the ceramic resonator to circuit ground, wherein the first building block circuit is a one pole filter circuit and a transfer function of the first building block circuit includes one finite transmission zero at a frequency higher than the passband frequency range.

2. The apparatus of claim 1, wherein the bandpass circuit includes a second building block circuit that is a one pole elliptical filter circuit and includes a third capacitor and one ceramic resonator circuit element coupled in series, wherein the transfer function of the bandpass circuit includes the finite transmission zero of the first building block circuit at the frequency higher than the passband frequency range and includes the finite transmission zero of the second building block circuit at a frequency lower than the passband frequency range.

3. The apparatus of claim 2,
wherein the second building block circuit includes a second circuit path from an input to an output of the second building block circuit, and the third capacitor and the ceramic resonator circuit element are coupled between the second circuit path and circuit ground.

4. The apparatus of claim 1, wherein the bandpass circuit includes at least one second building block circuit that is a one pole elliptical filter circuit, includes one ceramic resonator circuit element and a transfer function of the second building block circuit includes one finite transmission zero, wherein the transfer function of the bandpass circuit includes the finite transmission zero of the first building block circuit at the frequency lower than the passband frequency range and includes the finite transmission zero of the at least one second building block circuit at the same or a different frequency lower than the passband frequency range.

5. The apparatus of claim 4, wherein the first building block circuit includes a first capacitor coupled in series to the ceramic resonator circuit element, wherein the ceramic resonator circuit element of the first building block circuit is coupled to the first capacitor and circuit ground, and
wherein the at least one second building block circuit includes a second capacitor coupled in series to the one ceramic resonator circuit element of the second building block circuit, and the one ceramic resonator circuit element of the second building block circuit is coupled to the second capacitor and circuit ground.

6. The apparatus of claim 1, wherein the bandpass circuit includes at least one second building block circuit that is a one pole elliptical filter circuit, includes one ceramic resonator circuit element and a transfer function of the second building block circuit includes one finite transmission zero, wherein the transfer function of the bandpass circuit includes the finite transmission zero of the first building block circuit at the frequency higher than the passband frequency range and includes the finite transmission zero of the at least one second building block circuit at the same or different frequency higher than the passband frequency range.

7. The apparatus of claim 6, wherein the first building block circuit includes the ceramic resonator circuit element coupled between a first capacitor and a second capacitor, and the first capacitor and the second capacitor are coupled to the first ceramic resonator circuit element of the first building block circuit and circuit ground, and
wherein the at least one second building block circuit includes a third capacitor coupled in series to the one ceramic circuit element of the second building block circuit, and the one ceramic circuit element is coupled to circuit ground.

8. The apparatus of claim 1, wherein the first building block circuit is included in N building block circuits, wherein each of the N building block circuits includes only one ceramic resonator circuit element and a transfer function of each of the N building block circuits includes one finite transmission zero, wherein a transfer function of the bandpass circuit includes finite transmission zeros of M of the N building block circuits at frequencies lower than the passband frequency range and finite transmission zeros of N−M of the building block circuits at frequencies higher than the passband frequency range, wherein N and M are positive integers and N>M.

9. The apparatus of claim 1, wherein the bandpass circuit is operatively coupled to bandpass processing circuitry.

10. An apparatus comprising:
an antenna diplexer circuit including:
a lower frequency channel configured to carry radio frequency (RF) signals of a first range of frequencies, wherein the lower frequency channel includes an M-pole elliptical filter circuit including M building block circuits each including a ceramic resonator circuit element arranged between an input and an output of an input/output circuit path of the building block circuit, wherein a transfer function of the lower frequency channel includes M finite transmission zeros on a higher frequency side of a passband of the lower frequency channel, and wherein M is a positive integer greater than zero; and
a higher frequency channel configured to carry radio frequency (RF) signals of a second range of frequencies higher than the first range of frequencies, wherein the higher frequency channel includes an N-pole elliptical filter circuit including N building block circuits each including a ceramic resonator circuit element, wherein a transfer function of the lower frequency channel includes N finite transmission zeros on a lower side of the passband of the higher frequency channel, and wherein N is a positive integer greater than zero.

11. The apparatus of claim 10, wherein the higher frequency channel includes N circuit blocks and a bandpass circuit, wherein a circuit block of the N circuit blocks includes a capacitor and one ceramic resonator circuit element of the N ceramic circuit elements, wherein the capacitor is coupled in series to the one ceramic resonator circuit element, and the one ceramic resonator circuit element is coupled to the capacitor and circuit ground.

12. The apparatus of claim 10, wherein the lower frequency channel includes M circuit blocks and a bandpass circuit, wherein a circuit block of the M circuit blocks includes a capacitor and one ceramic resonator circuit element of the M ceramic circuit elements, wherein the capacitor is coupled to the one ceramic resonator circuit element and circuit ground.

13. The apparatus of claim 10, including an antenna operatively coupled to a port common to the lower frequency channel and the higher frequency channel.

14. The apparatus of claim 10, wherein the antenna diplexer circuit is operatively coupled to baseband processing circuitry.

15. A wireless base station comprising:
a radio frequency (RF) antenna; and
a bandpass circuit having a passband frequency range, wherein the bandpass circuit includes a first building block circuit including one ceramic resonator circuit element, wherein the building block circuit is a one pole filter circuit and a transfer function of the first building block circuit includes one finite transmission zero, and wherein a transfer function of the bandpass circuit includes the finite transmission zero at one of a frequency lower than the passband frequency range or a frequency higher than the passband frequency range.

16. The wireless base station of claim 15, wherein the bandpass circuit includes a second building block circuit that is a one pole filter circuit and a transfer function of the second building block circuit includes one finite transmission zero, wherein the second building block circuit includes one ceramic resonator circuit element, wherein the transfer function of the bandpass circuit includes the finite transmission zero of the first building block circuit at the frequency lower than the passband frequency range and includes the finite transmission zero of the second building block circuit at the frequency higher than the passband frequency range.

17. The wireless base station of claim 15, wherein the bandpass circuit includes at least one second building block circuit that is a one pole filter circuit, includes one ceramic resonator circuit element and a transfer function of the second building block circuit includes one finite transmission zero, wherein the transfer function of the bandpass circuit includes the finite transmission zero of the first building block circuit at the frequency lower than the passband frequency range and includes the finite transmission zero of the at least one second building block circuit at the same or a different frequency lower than the passband frequency range.

18. The wireless base station of claim 15, wherein the bandpass circuit includes at least one second building block circuit that is a one pole filter circuit, includes one ceramic resonator circuit element and a transfer function of the second building block circuit includes one finite transmission zero, wherein the transfer function of the bandpass circuit includes the finite transmission zero of the first building block circuit at the frequency higher than the passband frequency range and includes the finite transmission zero of the at least one second building block circuit at the same or different frequency higher than the passband frequency range.

19. The wireless base station of claim 15, wherein the first building block circuit is included in an N-pole filter circuit that includes N ceramic resonator circuit elements, wherein a transfer function of the filter circuit includes N finite transmission zeros.

20. The wireless base station of claim 15, including baseband processing circuitry operatively coupled to the bandpass circuit.
